(19) United States
(12) Patent Application Publication
(10) Pub. No.: US 2013/0141100 A1
(43) Pub. Date: Jun. 6, 2013

(54) ANOMALY DETECTION SYSTEM FOR WIRELINE CABLES

(71) Applicants: Sherif Labib, Sugar Land, TX (US); Matthew R. Hackworth, Manvel, TX (US); Richard L. Christie, Sugar Land, TX (US); David P. Smith, Sugar Land, TX (US)

(72) Inventors: Sherif Labib, Sugar Land, TX (US); Matthew R. Hackworth, Manvel, TX (US); Richard L. Christie, Sugar Land, TX (US); David P. Smith, Sugar Land, TX (US)

(73) Assignee: Schlumberger Technology Corporation, Sugar Land, TX (US)

(21) Appl. No.: 13/595,758

(22) Filed: Aug. 27, 2012

Related U.S. Application Data
(60) Provisional application No. 61/527,197, filed on Aug. 25, 2011.

(51) Int. Cl. G01R 31/08

(52) U.S. Cl. CPC G01R 31/083
USPC 324/333; 324/539; 324/537

(57) ABSTRACT

An embodiment of a method for detecting an anomaly in at least a portion of a wireline cable, comprises providing at least one wireline cable, providing a wireline surface equipment system comprising an anomaly detection system and disposing the anomaly detection system adjacent the wireline cable, operating the surface equipment to enable the wireline cable to pass by the anomaly detection system, operating the anomaly detection system to detect the presence of an anomaly in at least a portion of the wireline cable, the anomaly detection system generating an output when an anomaly is detected, and sending the output of the anomaly detection system to a control unit.

### CROSS-REFERENCE TO RELATED APPLICATION

This application claims priority as a nonprovisional of U.S. Provisional Patent Application No. 61/527,197, filed Aug. 25, 2011, the disclosure of which is incorporated by reference herein in its entirety.

### BACKGROUND

The statements in this section merely provide background information related to the present disclosure and may not constitute prior art.

The present disclosure is related in general to wellsite and wellbore equipment such as oilfield surface equipment, downhole wellbore equipment and methods, and the like.

Wireline cables for use in the oil and gas industry may be produced in a variety of designs, one of which is known as a heptacable, indicated generally at 5 in FIG. 1. A typical wireline heptacable 5 arrangement is shown in FIG. 1, wherein a cable core 3 comprising seven conductors 6 (only one indicated) is surrounded on an exterior portion thereof by an inner armor wire layer 1 and an outer armor wire layer 2. The individual armor wires of the layers 1 and 2 may be constructed of a steel material, a steel alloy material or the like. The armor wire layers 1 and 2 provide axial strength to the cable 5 during use within a wellbore. Other cable designs may comprise a monocable (wherein a cable core, such as the cable core 3 comprises a single conductor), a coaxial cable (wherein a cable core, such as the cable core 3 comprises a central conductor and a coaxial serve layer separated from the central conductor by an insulation material and the like), a triad cable (wherein a cable core, such as the cable core 3 comprises a three conductors), and a quad cable (wherein a cable core, such as the cable core 3 comprises a four conductors), as will be appreciated by those skilled in the art.

During routine usage in the oilfield service industry, wireline cables, such as the cable 5, may last many years and/or operational cycles. However, there are operational environments where the armor wires of the cable, such as the armor wires 1 and 2 of the cable 5 in FIG. 1, may be damaged. The damage mechanism may be mechanical (such as an impact by another metal object during rig-up or run in hole), chemical (some type of corrosion attachment, such as from produced hydrocarbons or engineered fluids placed in the wellbore or the like), or other types of damage. In any case, a damaged armor wire may result in a lowered strength rating of the cable. In a severe case, enough armor wires may be damaged such that the entire cable may break during a routine wellbore operation.

It remains desirable to provide improvements in wireline cables and/or downhole assemblies.

### SUMMARY

An embodiment of a method for detecting an anomaly in at east a portion of a wireline cable, comprises providing at least one wireline cable, providing a wireline surface equipment system comprising an anomaly detection system and disposing the anomaly detection system adjacent the wireline cable, operating the surface equipment to enable the wireline cable to pass by the anomaly detection system, operating the anomaly detection system to detect the presence of an anomaly in at least a portion of the wireline cable, the anomaly detection system generating an output when an anomaly is detected, and sending the output of the anomaly detection system to a control unit. In an embodiment, sending comprises sending the results of the anomaly detection system to the control unit in real time. In an embodiment, operating the anomaly detection system comprises operating a magnetic flux inspection system. In an embodiment, operating the anomaly detection system comprises operating a weak magnetic inspection system. In an embodiment, operating the anomaly detection system comprises a loss of metallic cross-sectional area inspection system. In an embodiment, operating the anomaly detection system comprises operating a localized flaw inspection system.

In an embodiment, providing at least one wireline cable comprises providing a heptacable, wherein the heptacable comprises a plurality of conductors surrounded by at least one layer of armor wires. In an embodiment, the anomaly detection system is configured to determine a magnitude of a detected anomaly. In an embodiment, providing at least one wireline cable comprises providing a cable having a tool disposed on a free end thereof and further comprising disposing the wireline cable and tool into a wellbore penetrating a subterranean formation and conducting at least one wellbore operation with the wireline cable and tool. The wellbore operation may comprise a logging operation. The wellbore operation may comprise an intervention operation. The wellbore operation may comprise a pressure and sampling operation. The wellbore operation may comprise a formation evaluation operation.

In an embodiment, the anomaly detection system is configured to detect an anomaly comprising at least one of pitted corrosion, cracked wires, and broken wires. In an embodiment, providing at least one wireline cable comprises providing a wireline cable comprising a cable core, the cable core comprising at least one conductor and at least one layer of armor wires disposed around the cable core. The anomaly detection system may be configured configured to detect an anomaly in the armor wires of the wireline cable. The anomaly detection system may be configured to detect an anomaly in the conductor or conductors of the wireline cable. In an embodiment, the method further comprises ceasing operation of the system when the anomaly detection system detects an anomaly exceeding a predetermined value or values. The control unit and/or the anomaly detection system may ceases operation of the system based on the detected anomaly. In an embodiment, the anomaly detection system comprises a changeable or replaceable sensor for use with multiple diameters of wireline cables.

### BRIEF DESCRIPTION OF THE DRAWINGS

These and other features and advantages of the present invention will be better understood by reference to the following detailed description when considered in conjunction with the accompanying drawings wherein:

FIG. 1 is a schematic cross-sectional view of a prior art cable disposed against an object.

FIG. 2 is a schematic view of a wireline surface equipment comprising an embodiment of an anomaly detection system of the present disclosure.

FIG. 3 is a perspective schematic view of an embodiment of an anomaly detection system of the present disclosure.

### DETAILED DESCRIPTION

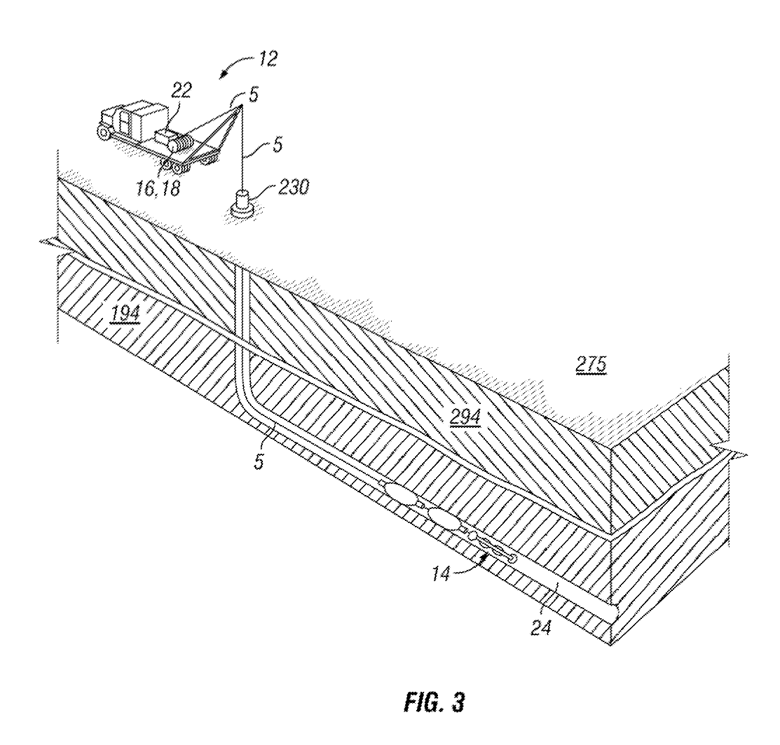

Referring to FIGS. 2 and 3, an anomaly detection system 10 is mounted as part of the wireline surface equipment, indicated generally at 12, disposed at an oilfield 275 and adjacent the wireline cable 5, such as while the wireline cable 5 is moving under tension. The system 10 may be a light weight system such that the presence of the detection system 10 does not significantly change a tension measurement of the cable 5 when compared to equipment 12 that does not comprise a detection system 10.

The anomaly detection system 10 for is configured to detect the status of at least a portion of the wireline cable, including the armor wires 1 and 2 thereof. The system 10 may be configured to detect anomalies such as, but not limited to, corrosion, pitting, abrasion, cracking and/or other anomalies. The detection resolution of the system 20 tolerates a range of wireline cable 5 speeds that are currently used in the wireline applications. The anomaly detection system 10 may further be configured to measure and determine the diameter of the wireline cable 5 during operation of the system 10.

The wireline cable 5 may comprises a downhole tool or tools 14 disposed on a free end thereof. The wireline cable 5 is disposed on a storage drum 16 having a winch 18 powering the drum 16 and is routed through rig-up equipment 20 such as, but not limited to, pressure control equipment 230 and the like, as will be appreciated by those skilled in the art for use within a wellbore 24 penetrating a subterranean formation or formations 194, 294.

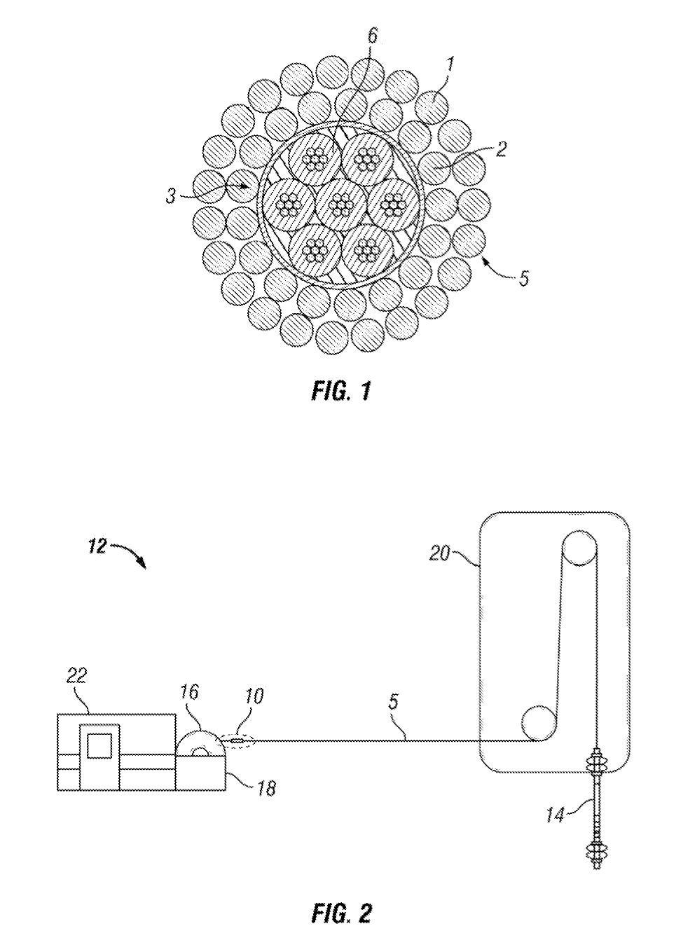

The winch 18, rig-up equipment 20, downhole tool 14, and anomaly detection system 10 are in communication with a control or wireline unit 22. The downhole tool 14 may comprise a logging tool or similar tool configured to perform at least one wellbore operation, such as a logging operation, within a wellbore penetrating a subterranean formation (not shown). The tool 14 may comprise an intervention tool for performing an intervention operation, a pressure and sampling tool for performing a pressure and sampling operation, and/or a formation evaluation tool for performing a formation evaluation operation. The cable 5 may comprise, but is not limited to, a monocable (wherein the cable core comprises a single conductor), a coaxial cable (wherein the cable core comprises two conductors—a central conductor and an outer served conductor), a triad cable (wherein the cable core comprises three conductors), a quad cable (wherein the cable core comprises four conductors), or a heptacable, such as the heptacable 5 shown in FIG. 1.

The anomaly detection system 10 may be configured to detect the anomalies using an electromagnetic inspection method and may be deployed in the field and mounted as part of the wireline surface equipment to inspect the cable 5 while it is moving under tension. The anomaly detection system 10 may provide a continuous real time evaluation of the cable 5 condition and/or cable diameter and may be equipped with an alarm system which is triggered when anomalies are detected thereby.

The anomaly detection system 10 may be configured to focus on anomalies in the armor wires 1 and 2, the conductors 6 of the cable core 3, or both. The anomaly detection system 10 may further be configured to differentiate between mud residue and other solid materials (such as those disposed on the exterior surface of the cable 5 or the like) in determining whether or not an anomaly exists. The anomaly detection technique and methodology is configured to detect those anomalies in the various portions 1, 2, 3, 6 of the wireline cable 5. The head assembly of the detection system 10 is universal or adaptable for different diameters of wireline cable 5 and may further comprise a changeable or replaceable sensor within the same system 10 to accommodate different cables 5.

In an embodiment, the anomaly detection system 10 may be configured to utilize a magnetic flux inspection system to detect anomalies in the wireline cable 5. The magnetic flux inspection system 10 may comprise commercially available systems such as those from NDT Technologies, Inc., itRobotics, or similar type magnetic flux inspection system utilized for wire ropes used in the mining industry, for wire ropes of cranes, for ski lifts and/or other similar applications. The anomaly detection system 10 may be configured to utilize a “Weak Magnetic inspection”, commercially available from TCK Wire Rope Inspection Technology Co. Ltd.

In an embodiment, the magnetic flux inspection system 10 is configured to utilize loss of metallic cross-sectional area (LMA) inspection, which is suitable for detection of loss anomalies caused by corrosion and wear. In an embodiment, the magnetic flux inspection system 10 utilizes localized flaw (LF) inspection, which is suitable for the detection cracks and broken wires, in an embodiment, the inspection system comprises dual function electromagnetic wire rope inspection systems, which are also commercially available.

The anomaly detection system 10 may be configured to detect the following anomalies including, but not limited to, pitted corrosion, such as pitted corrosion in the armor wires 1 and 2, cracked wires due to corrosion, and broken wires due to mechanical damage or embrittlement. The system 10 may be advantageously configured to detect flaws and/or anomalies during real-time operation of the wireline cable 5 and/or tool 14 and to output the results of the inspection to a control system, wireline unit 22, or the like during a wellbore operation. When an anomaly is detected by the system 10 and communicated to the control system or wireline unit 22, an operator of the systems 10 and 22 is able to determine a course of action with respect to the wireline cable 5. In an embodiment, the system 10 and/or the wireline unit/control system 22 may employ failsafe methods in order to stop operation and/or use of the wireline cable 5 when a detected anomaly exceeds a predetermined condition or conditions.

The anomaly detection system 10 may be configured to determine whether anomalies exist in the armor wires 1 and 2, the conductor wires 6 of the cable core 3, or both the armor wires 1 and 2 and the conductor wires 6 of the cable core 3. The system 10 may be configured to detect anomalies in portions of wireline cables having a smooth outer surface, such as a polymeric outer layer or the like.

The anomaly detection system 10 may be configured to determine a magnitude of the anomaly, such as by detecting and measuring a dimension of the anomaly.

The preceding description has been presented with references to certain exemplary embodiments of the invention. Persons skilled in the art and technology to which this invention pertains will appreciate that alterations and changes in the described structures and methods of operation can be practiced without meaningfully departing from the principle, and scope of this invention. Accordingly, the foregoing description should not be read as pertaining only to the precise structures described and shown in the accompanying drawings. Instead, the scope of the application is to be defined by the appended claims, and equivalents thereof.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. In particular, every range of values (of the form, “from about a to about b,” or, equivalently, “from approximately a to b,” or, equivalently, “from approximately a-b”) disclosed herein is to be understood as referring to the power set (the set of all subsets) of the respective range of values. Accordingly, the protection sought herein is as set forth in the claims below.

What is claimed is:

1. A method for detecting an anomaly in at least a portion of a wireline cable, comprising
providing at least one wireline cable;
providing a wireline surface equipment system comprising an anomaly detection system and disposing the anomaly detection system adjacent the wireline cable;
operating the surface equipment to enable the wireline cable to pass by the anomaly detection system;
operating the anomaly detection system to detect the presence of an anomaly in at least a portion of the wireline cable, the anomaly detection system generating an output when an anomaly is detected; and
sending the output of the anomaly detection system to a control unit.

2. The method of claim 1 wherein sending comprises sending the results of the anomaly detection system to the control unit in real time.

3. The method of claim 1 wherein operating the anomaly detection system comprises operating a magnetic flux inspection system.

4. The method of claim 1 wherein operating the anomaly detection system comprises operating a weak magnetic inspection system.

5. The method of claim 1 wherein operating the anomaly detection system comprises operating a loss of metallic cross-sectional area inspection system.

6. The method of claim 1 wherein operating the anomaly detection system comprises operating a localized flaw inspection system.

7. The method of claim 1 wherein providing at least one wireline cable comprises providing a heptacable, wherein the heptacable comprises a plurality of conductors surrounded by at least one layer of armor wires.

8. The method of claim 1 wherein the anomaly detection system is configured to determine a magnitude of a detected anomaly.

9. The method of claim 1 wherein providing at least one wireline cable comprises providing a cable having a tool disposed on a free end thereof and further comprising disposing the wireline cable and tool into a wellbore penetrating a subterranean formation and conducting at least one wellbore operation with the wireline cable and tool.

10. The method of claim 9 wherein the wellbore operation comprises a logging operation.

11. The method of claim wherein the wellbore operation comprises an intervention operation.

12. The method of claim 9 wherein the wellbore operation comprises a pressure and sampling operation.

13. The method of claim 9 wherein the wellbore operation comprises a formation evaluation operation.

14. The method of claim 1 wherein the anomaly detection system is configured to detect an anomaly comprising at least one of pitted corrosion, cracked wires, and broken wires.

15. The method of claim 1 wherein providing at least one wireline cable comprises providing a wireline cable comprising a cable core, the cable core comprising at least one conductor and at least one layer of armor wires disposed around the cable core.

16. The method of claim 15 wherein the anomaly detection system is configured to detect an anomaly in the armor wires of the wireline cable.

17. The method of claim 15 wherein the anomaly detection system is configured to detect an anomaly in the conductor or conductors of the wireline cable.

18. The method of claim 1 wherein further comprising ceasing operation of the system when the anomaly detection system detects an anomaly exceeding a predetermined value or values.

19. The method of claim 18 wherein the control unit and/or the anomaly detection system ceases operation of the system based on the detected anomaly

20. The method of claim 1 wherein the anomaly detection system comprises a changeable or replaceable sensor for use with multiple diameters of wireline cables.
